(19) United States
(12) Patent Application Publication
(10) Pub. No.: US 2005/0247859 A1
(43) Pub. Date: Nov. 10, 2005

(54) Package structure of a stack-type light-sensing element and package method thereof

(76) Inventors: Chih-Ming Hsu, Taoyuan (TW); Chung-Cheng Lin, Taoyuan (TW); Chin-Ting Lee, Taoyuan (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/181,935

(22) Filed: Jul. 15, 2005

(30) Foreign Application Priority Data
Mar. 12, 2004 (TW) 093137296

(51) Int. Cl. H01L 27/00

(52) U.S. Cl. 250/208.1

(57) ABSTRACT

The present invention discloses a package structure of a stack-type light-sensing element and a package method thereof, wherein firstly, a substrate is provided; next, a signal-processing IC chip and a light-sensing chip are sequentially stacked above the substrate in bottom-up sequence; next, lead lines are used to electrically connect the substrate with the signal-processing IC chip and the light-sensing chip in order to form a unitary light-sensing element. The present invention has the advantages that light-sensor signals are directly processed and then output to a display device, and that the volume of a light-sensing element can be reduced to such an extent that it can be easily applied to miniature electronic products. In contrast with the conventional light-sensing element needing massive volume of electronic circuits to process signal and also needing minute and complicated assemblage, the present invention has superior novelty and futurity.

### BACKGROUND OF THE INVENTION

1. Field of the Invention

The present invention relates to a stack-type light-sensing element, particularly to a package structure of a stack-type light-sensing element and a package method thereof,

2. Description of the Related Art

Light-sensing element can be applied to alarm systems, photometers, or fire detection, biological inspection, air pollution detection devices, etc.

Refer to FIG. 1 a section view of the package structure of a conventional light-sensing element, and also refer to FIG. 2 a top view of the same structure in FIG. 1. The conventional light-sensing element 1 comprises: a circuit board 10, a signal-processing element assembly 12 and a light-sensing unit 14.

However, in the aforementioned package structure of the conventional light-sensing element, the signal-processing element assembly 12 and the light-sensing unit 14 are disposed on the same plane of the circuit board 10, which results in a large volume of the entire product; thus, it is hard to apply to miniature electronic products; further, the assemblage thereof is pretty minute and complicated.

Accordingly, the present invention proposes a package structure of a stack-type light-sensing element and a package method thereof in order to overcome the abovementioned problems.

### SUMMARY OF THE INVENTION

The primary objective of the present invention is to provide a package structure of a stack-type light-sensing element and a package method thereof, wherein a substrate, a signal-processing IC (integrated circuit) chip and a light-sensing chip are sequentially stacked to combine together, and then, electrically connected to each other via lead lines to form a light-sensing element so that the volume of the light-sensing element can be reduced to such as an extent that it can be easily applied to miniature electronic products.

To achieve the aforementioned objective, the present invention proposes a package structure of a stack-type light-sensing element, which comprises: a substrate; a signal-processing IC chip, disposed on the substrate; and a light-sensing chip, stacked on the signal-processing IC chip; and multiple lead lines, used to electrically connect the substrate with the signal-processing IC chip and the light-sensing chip; wherein all the abovementioned elements are packaged to form a unitary light-sensing element via a glue-dispensing, a die-casting or a cover-encasing method.

The present invention also proposes a package method of a stack-type light-sensing element, which comprises the following steps: firstly, providing a substrate; stacking a signal-processing IC chip on the substrate with its front face upward; further stacking a light-sensing chip on the front face of the signal-processing IC chip via a flip-chip fabrication process; and lastly, electrically connecting the substrate with the signal-processing IC chip via multiple lead lines in order to combine all the elements together to form a unitary light-sensing element.

The present invention further proposes another package method of a stack-type light-sensing element, which comprises the following steps: firstly, providing a substrate; stacking a signal-processing IC chip on the substrate with its back face upward via a flip-chip fabrication process; further stacking a light-sensing chip on the back face of the signal-processing IC chip; and lastly, electrically connecting the substrate with the light-sensing chip via multiple lead lines in order to combine all the elements together to form a unitary light-sensing element.

To enable the objectives, technical contents, characteristics and accomplishments of the present invention to be more easily understood, the embodiments of the present invention are to be described below in detail in cooperation with the attached drawings.

### BRIEF DESCRIPTION OF THE DRAWINGS

FIG. 1 is a section view of the package structure of a conventional light-sensing element.

FIG. 2 is a top view of the same structure in FIG. 1.

FIG. 3 is a section view of the package structure of a stack-type light-sensing element according to one embodiment of the present invention.

FIG. 4 is a top view of the same structure in FIG. 3.

FIG. 5 is a section view of the package structure of a stack-type light-sensing element according to another embodiment of the present invention.

FIG. 6 is a top view of the same structure in FIG. 5.

FIG. 7 is a section view of the package structure of a stack-type light-sensing element according to further another embodiment of the present invention.

FIG. 8 is a top view of the same structure in FIG. 7.

FIG. 9(a) to FIG. 9(d) are section views showing the steps of the package method of a stack-type light-sensing element according to the present invention.

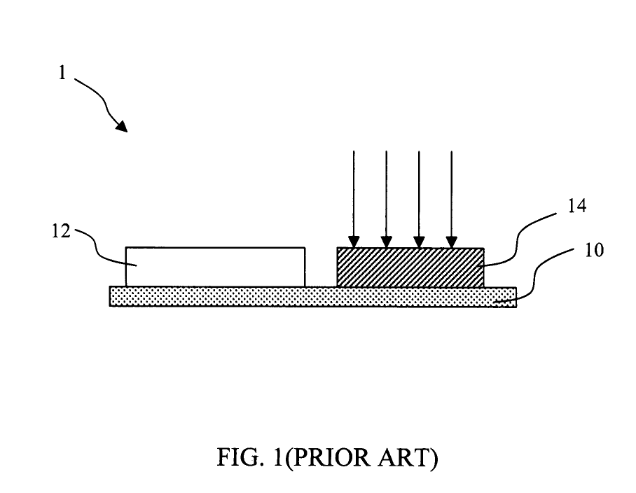

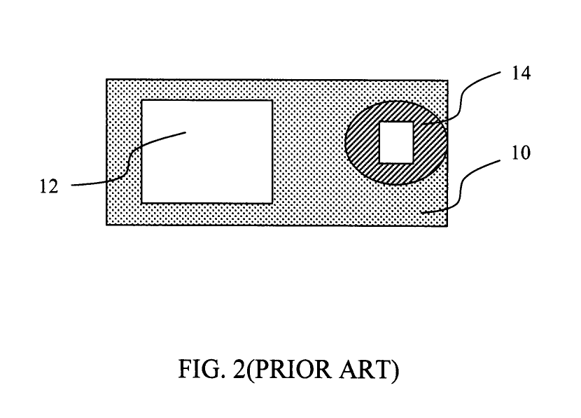

### DETAILED DESCRIPTION OF THE INVENTION

To meet the requirements of current miniature electronic products, such as mobile phones, watches, portable flash memories, personal digital assistants, etc., the present invention proposes a package structure of a stack-type light-sensing element and a package method thereof in order to enable a light-sensing element to apply to miniature electronic products so that the user can carry those about conveniently.

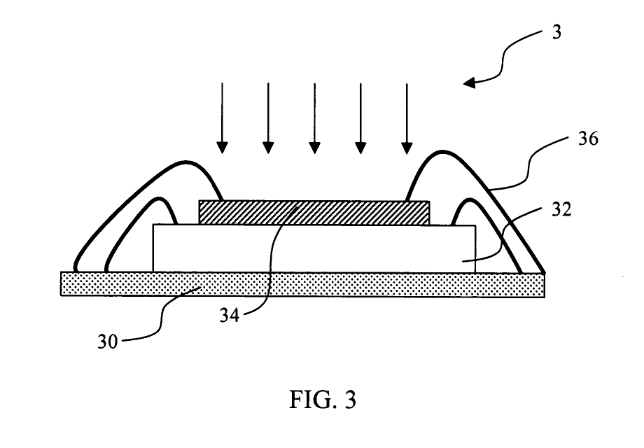

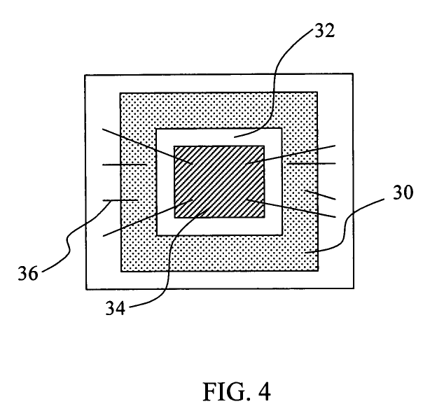

Refer to FIG. 3 a section view of the package structure of a stack-type light-sensing element according to one embodiment of the present invention, and also refer to FIG. 4 a top view of the same structure in FIG. 3. The stack-type light-sensing element 3 comprises: a substrate 30, which may be a circuit board, a metallic substrate, or a ceramic substrate; a signal-processing IC chip 32, which can amplify signal; a light-sensing chip 34, which may be made of a transparent GaN (Gallium Nitride) material or an opaque silicon material; and multiple lead lines 36, which may be made of gold or aluminum; wherein the signal-processing IC chip 32 and the light-sensing chip 34 are sequentially stacked above the substrate 30 in bottom-up sequence, and the lead lines 36 are separately used to electrically connect the substrate 30 with the signal-processing IC chip 32 and electrically connect the substrate 30 with and the light-sensing chip 34 in order to form a unitary light-sensing element.

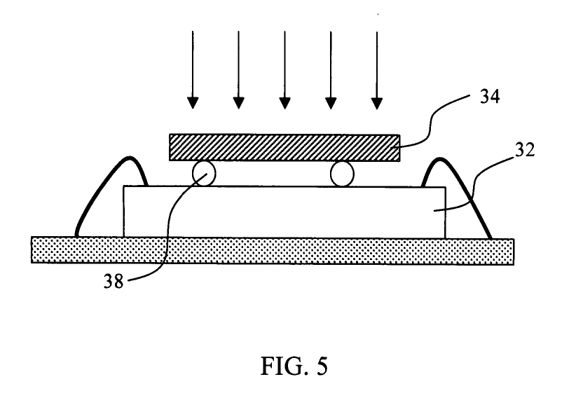

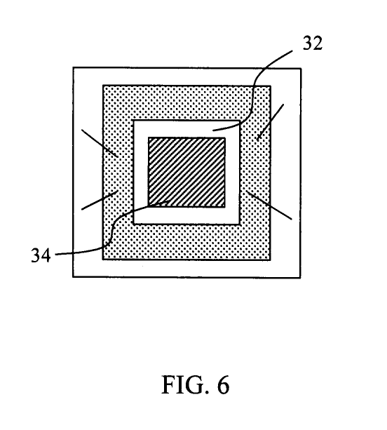

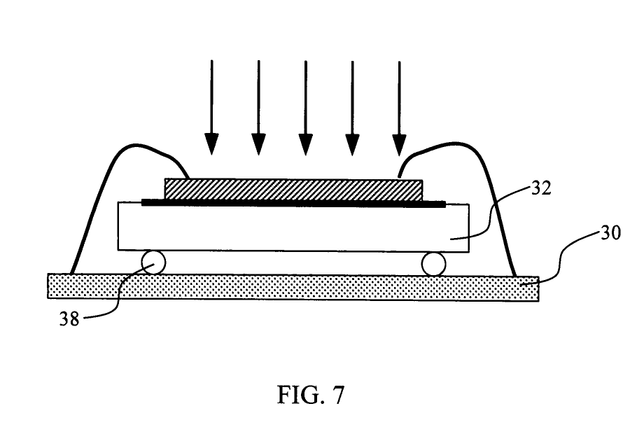

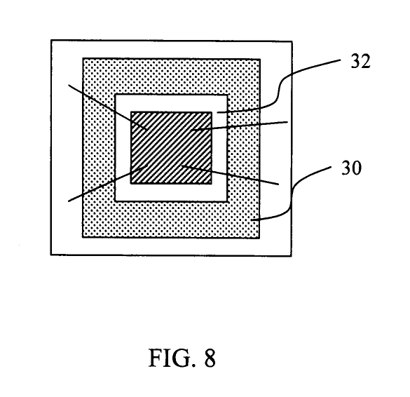

Further, multiple solder bumps 38, which are made of an electrically-conductive material, may be implanted on the front face of the signal-processing IC chip 32 and under the bottom of the light-sensing chip 34, as shown in FIG. 5 a section view of this structure and FIG. 6 the top view of the same structure in FIG. 5. Otherwise, the solder bumps 38 may also be implanted on the substrate 30 and interposed between the substrate 30 and the signal-processing IC chip 32, as shown in FIG. 7 a section view of this structure and FIG. 8 the top view of the same structure in FIG. 7.

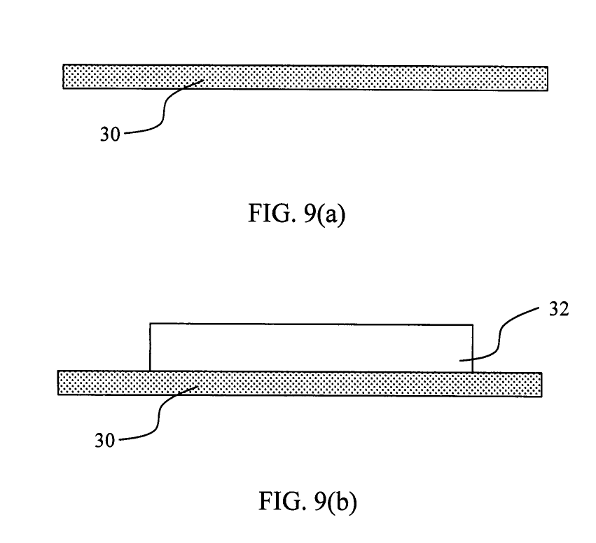

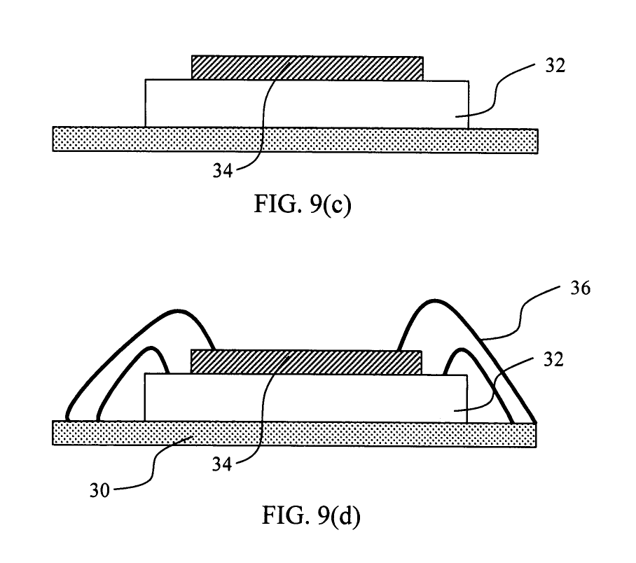

The present invention also proposes a package method of a stack-type light-sensing element. Refer to from FIG. 9(a) to FIG. 9(d) section views showing the steps of the package method according to the present invention. Firstly, a substrate 30 is provided, as shown in FIG. 9(a); next, a signal-processing IC chip 32 is stuck onto the substrate 30 with a silver paste, as shown in FIG. 9(b); next, a light-sensing chip 34 is stuck onto the signal-processing IC chip 32 with a non-conductive glue, as shown in FIG. 9(c); and lastly, multiple lead lines 36 are separately used to electrically connect the substrate 30 with the signal-processing IC chip 32 and electrically connect the substrate 30 with and the light-sensing chip 34, as shown in FIG. 9(d).

The package method of a stack-type light-sensing element according to the present invention can further comprises a step of implanting multiple solder bumps 38 on the signal-processing IC chip 32 before the step shown in FIG. 9(c), and the step shown in FIG. 9(c) will be replaced by installing the light-sensing chip 34 onto the signal-processing IC chip 32 via a heating method and a high-frequency oscillation. Otherwise, the package method according to the present invention can further comprises a step of implanting multiple solder bumps 38 on the substrate 30 before the step shown in FIG. 9(b), and the step shown in FIG. 9(b) will be replaced by installing the signal-processing IC chip 32 onto the substrate 30 via a heating method and a high-frequency oscillation.

The present invention proposes a package structure of a stack-type light-sensing element and a package method thereof, wherein the conventional circuit of an electronic control element is redesigned and fabricated into a miniature signal-processing IC chip; then, this signal-processing IC chip, which amplifies signals, is installed on a substrate; next, a light-sensing chip, which may be a transparent GaN or an opaque silicon, is stuck onto the signal-processing IC chip to form a stack; and then, those chips are connected with the substrate via multiple lead lines to form a unitary light-sensing element. Thereby, the present invention can reduce the volume of a light-sensing element to such an extent that it can be easily applied to miniature electronic products.

Those embodiments described above are only to clarify the present invention to enable the persons skilled in the art to understand, make, and use the present invention but not intended to limit the scope of the present invention. Any equivalent modification or variation without departing from the spirit of the present invention disclosed herein is to be included within the scope of the claims stated below.

1. A package structure of a stack-type light-sensing element, comprising:
a substrate;
a signal-processing IC chip, installed on said substrate;
a light-sensing chip, installed on said signal-processing IC chip; and
multiple lead lines, separately used to electrically connect said substrate with said signal-processing IC chip and electrically connect said substrate with and said light-sensing chip.

2. The package structure of a stack-type light-sensing element according to claim 1, wherein said substrate is one of the group of a circuit board, a metallic substrate, and a ceramic substrate, which have circuit layouts.

3. The package structure of a stack-type light-sensing element according to claim 1, wherein said signal-processing IC chip includes an integrated circuit having the functions of amplifying and encoding signals.

4. The package structure of a stack-type light-sensing element according to claim 1, wherein said light-sensing chip is made of a transparent GaN (Gallium Nitride) material or an opaque silicon material.

5. The package structure of a stack-type light-sensing element according to claim 1, wherein said light-sensing chip is a light-sensing chip sensing ultraviolet ray with wavelength below 430 nm, or a light-sensing chip sensing visible ray with wavelength ranging from 430 to 710 nm, or a light-sensing chip sensing infrared ray with wavelength above 710 nm.

6. The package structure of a stack-type light-sensing element according to claim 1, wherein said lead lines is made of a gold alloy or an aluminum alloy.

7. The package structure of a stack-type light-sensing element according to claim 1, which further comprises multiple solder bumps implanted on said signal-processing IC chip and interposed between said signal-processing IC chip and said light-sensing chip.

8. The package structure of a stack-type light-sensing element according to claim 7, wherein said solder bumps is made of a gold alloy, a silver alloy, a tin alloy, or a cupric alloy.

9. The package structure of a stack-type light-sensing element according to claim 1, which further comprises multiple solder bumps implanted on said substrate and interposed between said substrate and said signal-processing IC chip.

10. The package structure of a stack-type light-sensing element according to claim 9, wherein said solder bumps is made of a gold alloy, a silver alloy, a tin alloy, or a cupric alloy.

11. A package method of a stack-type light-sensing element, comprising the following steps:
providing a substrate;
installing a signal-processing IC chip on said substrate;
installing a light-sensing chip on said signal-processing IC chip; and
electrically connecting said substrate with said signal-processing IC chip and electrically connecting said substrate with said light-sensing chip via multiple lead lines.

12. The package method of a stack-type light-sensing element according to claim 11, wherein said signal-processing IC chip is stuck onto said substrate with a conductive paste.

13. The package method of a stack-type light-sensing element according to claim 11, wherein said light-sensing chip is stuck onto said signal-processing IC chip with a conductive paste or a non-conductive paste.

14. The package method of a stack-type light-sensing element according to claim 11, which further comprises a step of implanting multiple solder bumps on said signal-processing IC chip before said step of “installing a light-sensing chip on said signal-processing IC chip”.

15. The package method of a stack-type light-sensing element according to claim 11, wherein said light-sensing chip is installed on said signal-processing IC chip via a heating method and a high-frequency oscillation.

16. The package method of a stack-type light-sensing element according to claim 14, which further comprises a step of implanting multiple solder bumps on said substrate before said step of “installing a signal-processing IC chip on said substrate”.

17. The package method of a stack-type light-sensing element according to claim 16, wherein said signal-processing IC chip is installed on said substrate via a heating method and a high-frequency oscillation.
